(19) United States
(12) Patent Application Publication
(10) Pub. No.: US 2026/0236079 A1
(43) Pub. Date: Aug. 13, 2026

(54) REGULATING DEVICE, CLOCK BUFFERING DEVICE, AND COMPUTING SYSTEM

(71) Applicant: SAMSUNG ELECTRONICS CO., LTD., Suwon-si (KR)

(72) Inventors: Daihyun LIM, Suwon-si (KR); Jaehyouk CHOI, Seoul (KR); Jaeho KIM, Seoul (KR); Myeongho HAN, Seoul (KR); Seungjun BAE, Suwon-si (KR); Yongsun LEE, Suwon-si (KR)

(73) Assignees: SAMSUNG ELECTRONICS CO., LTD., Suwon-si (KR); Seoul National University R&DB Foundation, Seoul (KR)

(21) Appl. No.: 19/460,536

(22) Filed: Jan. 27, 2026

(30) Foreign Application Priority Data
Feb. 10, 2025 (KR) 10-2025-0016956

(51) Int. Cl. G06F 1/30; G05F 1/46

(52) U.S. Cl. CPC G06F 1/305; G05F 1/467; G05F 1/468

(57) ABSTRACT

A regulating device includes a first regulator configured to supply first load current, based on a clock signal and an activation command received from a host device and a second regulator configured to supply second load current based on output voltage of the regulating device. The first regulator includes a control signal generator, a current adapter and a current supply circuit. The control signal generator is configured to generate a plurality of control signals, based on the clock signal and the activation command. The current adapter is configured to generate a plurality of adjustment values representing a degree of adjustment of the output voltage, based on at least some of the plurality of control signals. The current supply circuit is configured to supply the first load current, based on at least some of the plurality of control signals and the plurality of adjustment values.

### CROSS-REFERENCE TO RELATED APPLICATION

This application is based on and claims priority under 35 U.S.C. §119 to Korean Patent Application No. 10-2025-0016956, filed on February 10, 2025, in the Korean Intellectual Property Office, the disclosure of which is incorporated by reference herein in its entirety.

### BACKGROUND

The inventive concept relates to a regulating device for providing stable voltage.

Memory devices may store data received from host devices. The memory devices may sample and store data on the basis of clock signals received together with the data. In this case, the memory devices may buffer the clock signals received from the host devices by using clock buffers. The clock buffers may be supplied with power supply voltage from regulating devices in order to operate stably.

The regulating devices may provide stable voltage to other devices. Since the clock buffers operate based on the voltage supplied by the regulating devices, the regulating devices are required to supply stable voltage to the clock buffers so that the clock buffers may operate stably.

### SUMMARY

The inventive concept provides a regulating device for supplying stable load current to a load device.

According to an aspect of the inventive concept, there is provided a regulating device including a first regulator configured to supply first load current, based on a clock signal and an activation command received from a host device and a second regulator configured to supply second load current based on output voltage of the regulating device, wherein the first regulator includes a control signal generator configured to generate a plurality of control signals, based on the clock signal and the activation command, a current adapter configured to generate a plurality of adjustment values representing a degree of adjustment of the output voltage, based on at least some of the plurality of control signals, and a current supply circuit configured to supply the first load current, based on at least some of the plurality of control signals and the plurality of adjustment values.

According to another aspect of the inventive concept, there is provided a clock buffering device configured to receive a clock signal and an activation command from a host device and output a buffered clock signal based on the clock signal, the clock buffering device including a clock buffer configured to buffer the clock signal and output the buffered clock signal and a regulating device configured to supply first load current and second load current to the clock buffer, based on the clock signal and the activation command, wherein the regulating device includes a first regulator configured to supply the first load current, based on the clock signal and the activation command and a second regulator configured to supply the second load current based on output voltage of the regulating device, and wherein the first regulator includes a control signal generator configured to generate an activation control signal and a toggle control signal, based on the clock signal and the activation command, a current adapter configured to generate a plurality of adjustment values representing a degree of adjustment of the output voltage, based on the activation control signal and the toggle control signal, and a current supply circuit configured to supply the first load current, based on the activation control signal, the toggle control signal, and the plurality of adjustment values.

According to another aspect of the inventive concept, there is provided a computing system including a host device and a memory device configured to receive a clock signal and an activation command from the host device, wherein the memory device includes a clock buffering device configured to receive the clock signal and the activation command and output a buffered clock signal based on the clock signal, and the clock buffering device includes a clock buffer configured to buffer the clock signal and output the buffered clock signal and a regulating device configured to supply first load current and second load current to the clock buffer, based on the clock signal and the activation command, and wherein the regulating device includes a first regulator configured to supply the first load current, based on the clock signal and the activation command and a second regulator configured to supply the second load current based on output voltage of the regulating device, and wherein the first regulator includes a control signal generator configured to generate a plurality of control signals, based on the clock signal and the activation command, a current adapter configured to generate a plurality of adjustment values representing a degree of adjustment of the output voltage, based on at least some of the plurality of control signals, and a current supply circuit configured to supply the first load current, based on at least some of the plurality of control signals and the plurality of adjustment values.

### BRIEF DESCRIPTION OF THE DRAWINGS

Embodiments will be more clearly understood from the following detailed description taken in conjunction with the accompanying drawings in which:

FIG. 1 is a block diagram showing a computing system including a memory device, according to an embodiment;

FIG. 2 is a diagram showing a clock buffering device according to an embodiment;

FIG. 3 is a diagram showing a regulating device according to an embodiment;

FIG. 4 is a diagram showing a control signal generator in a regulating device according to an embodiment;

FIG. 5 is a diagram showing a current adapter in a regulating device according to an embodiment;

FIG. 6 is a diagram showing a current supply circuit in a regulating device according to an embodiment;

FIG. 7 is a diagram showing an active current supply circuit in a regulating device according to an embodiment;

FIG. 8 is a diagram showing a toggle current supply circuit in a regulating device according to an embodiment;

FIG. 9 is a diagram showing a second regulator in a regulating device according to an embodiment;

FIG. 10 is a timing diagram showing changes in signal values, current values, and voltage values according to operations of a regulating device according to an embodiment; and

FIG. 11 is a diagram showing an example of a computing system including a clock buffering device according to embodiments.

### DETAILED DESCRIPTION OF THE EMBODIMENTS

Hereinafter, embodiments are described in detail with reference to the accompanying drawings.

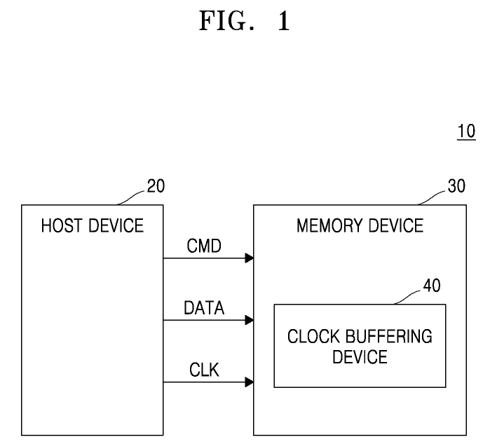

FIG. 1 is a block diagram showing a computing system 10 including a memory device 30, according to an embodiment.

Referring to FIG. 1, the computing system 10 according to an embodiment may include a host device 20 and the memory device 30.

In an embodiment, the computing system 10 may be implemented as a personal computer (PC), a data server, an ultra mobile PC (UMPC), a workstation, a netbook, a network-attached storage (NAS), a smart television, an Internet of Things (IoT) device, an automobile, or a portable electronic product. The portable electronic product may include a laptop computer, a mobile phone, a smartphone, a tablet PC, a personal digital assistant (PDA), an enterprise digital assistant (EDA), a digital still camera, a digital video camera, an audio device, a portable multimedia player (PMP), a personal navigation device (PND), an MP3 player, a handheld game console, an e-book, a wearable device, etc.

The host device 20 may control all operations of the computing system 10. In an embodiment, the host device 20 may include a processor core, such as a central processing unit (CPU) and an application processor (AP), configured to control the computing system 10, or may include a computing node connected via a network.

The host device 20 may store data in the memory device 30 or read data stored in the memory device 30.

The host device 20 may transmit various types of commands CMD to the memory device 30. For example, the host device 20 may transmit a write command or a read command to the memory device 30.

In an embodiment, the host device 20 may transmit an activation command to the memory device 30. In this case, the activation command may represent a command indicating that data DATA or a clock signal CLK may be transmitted to the memory device 30. For example, when the activation command has a first value (e.g., 1), this may indicate that the host device 20 may transmit the data DATA or the clock signal CLK to the memory device 30. On the contrary, when the activation command has a second value (e.g., 0), this may indicate that the host device 20 does not transmit the data DATA or the clock signal CLK to the memory device 30. Based on such activation commands, the memory device 30 may determine in advance a time point, at which a clock buffering device 40 consumes current, and the amount of current consumed.

The host device 20 may transmit, to the memory device 30, the clock signal CLK or the data DATA corresponding to a command CMD. For example, the host device 20 may transmit a write command to the memory device 30, and may also transmit write data corresponding to the write command, together with the write command. In addition, the host device 20 may transmit the clock signal CLK (e.g., a WDQS signal) representing a sampling time of the write data, together with the write command.

The memory device 30 may include storage media for storing the data DATA according to the commands CMD received from the host device 20. The memory device 30 may be implemented as one of various types of devices. For example, the memory device 30 may be implemented as one of various types of devices, such as high bandwidth memory (HBM), static random-access memory (SRAM), and dynamic random-access memory (DRAM).

The memory device 30 may perform an operation corresponding to the command received from the host device 20. The memory device 30 may store the data DATA therein in response to the command CMD. In response to the command CMD, the memory device 30 may retrieve the data DATA corresponding to the command CMD from the inside of the memory device 30 and transmit the retrieved data DATA to the host device 20.

The memory device 30 may include the clock buffering device 40. The clock buffering device 40 may output a buffered clock signal that is generated by buffering the clock signal CLK received from the host device 20. The memory device 30 may sample the data DATA received from the host device 20, by using the buffered clock signal generated by the clock buffering device 40.

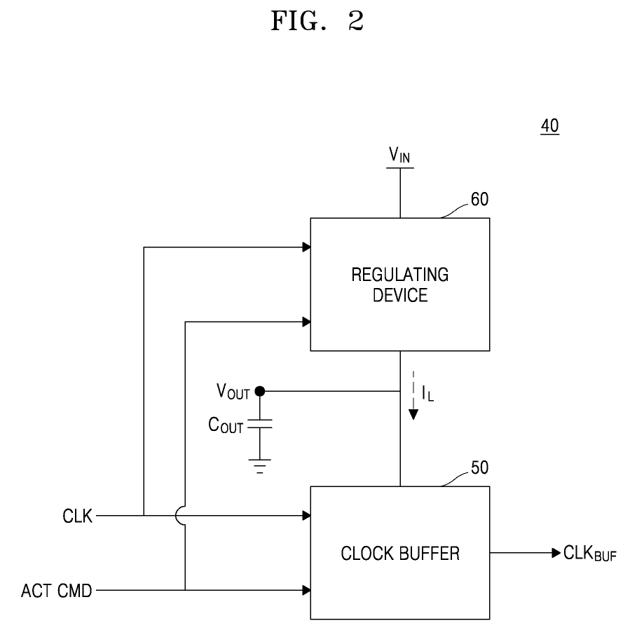

In an embodiment, the clock buffering device 40 may receive the clock signal CLK and the activation command. The clock buffering device 40 may output the buffered clock signal on the basis of the clock signal CLK and the activation command. The clock buffering device 40 may determine the time point, at which current is consumed, and the amount of current consumed, on the basis of the activation command, and may compensate for the current in the output voltage on the basis of the determined values. Accordingly, the clock buffering device 40 may prevent a sudden drop in the output voltage by compensating for the current in the output voltage. More specific structures and operations of the clock buffering device 40 are described below with reference to FIG. 2.

FIG. 2 is a diagram showing the clock buffering device 40 according to an embodiment.

Referring to FIG. 2, the clock buffering device 40 according to an embodiment may include a clock buffer 50 and a regulating device 60. The clock buffering device 40 may further include an output capacitor C_{OUT}.

The clock buffer 50 may receive the clock signal CLK and an activation command ACT CMD. The clock buffer 50 may buffer the clock signal CLK and output a buffered clock signal CLK_{BUF}. The clock buffer 50 may buffer the clock signal CLK by using devices, such as a current mode logic (CML) buffer, a CML-complementary metal-insulator-semiconductor (CMOS) level converter, and an inverter chain, thereby generating the buffered clock signal CLK_{BUF}. The clock buffer 50 may operate by using the output voltage V_{OUT} of the regulating device 60 as power supply voltage.

The regulating device 60 may provide power supply voltage to the clock buffer 50. For example, the regulating device 60 may include a low dropout (LDO) regulator.

The regulating device 60 may operate by using, as input voltage V_{IN}, the power supply voltage provided to the clock buffering device 40 by the memory device 30. The regulating device 60 may convert the input voltage V_{IN} and generate an output voltage V_{OUT}. In this case, the output voltage V_{OUT} generated by the regulating device 60 may have a voltage level that is required as the power supply voltage by the clock buffer 50. Since the clock buffer 50 operates based on the voltage provided by the regulating device 60, the regulating device 60 may be required to provide the clock buffer 50 with the output voltage V_{OUT} having a constant voltage level in order to ensure a stable operation of the clock buffer 50.

In this case, when the clock buffer 50 performs an operation of receiving the clock signal CLK from the host device 20 and generating the buffered clock signal CLK_{BUF}, the current consumed by the clock buffer 50 may increase. When the current consumed by the clock buffer 50 increases, the output voltage V_{OUT} of the regulating device 60 may change significantly. In order to prevent the output voltage V_{OUT} of the regulating device 60 from changing significantly, the output capacitor C_{OUT} may be connected between the clock buffer 50 and the regulating device 60.

One end of the output capacitor C_{OUT} may be connected to a node between the clock buffer 50 and the regulating device 60, and the other end thereof may be connected to a ground node. When the current consumed by the clock buffer 50 increases, the output capacitor C_{OUT} may supply stored charge to minimize a change in the voltage level of the output voltage V_{OUT}. However, in order to minimize changes in the voltage level of the output voltage V_{OUT} due to current consumption of the clock buffer 50, it may be required to use the output capacitor C_{OUT} having a large capacity. In this case, when the capacity of the output capacitor C_{OUT} increases, the output capacitor C_{OUT} also increases in size and occupies a large design area. As a result, it may not be possible to sufficiently increase the capacity of the output capacitor C_{OUT}. When the capacity of the output capacitor C_{OUT} is not sufficiently increased, a sudden drop in the output voltage V_{OUT} may occur when the clock buffer 50 is operating. Such a sudden drop in the output voltage V_{OUT} may cause jitter in the clock buffer 50.

In an embodiment, the regulating device 60 may receive the clock signal CLK and the activation command ACT CMD. The regulating device 60 may supply load current I_{L} to the clock buffer 50 on the basis of the clock signal CLK and the activation command ACT CMD. The regulating device 60 may prevent a sudden drop in the output voltage V_{OUT} by adjusting the amount of load current I_{L} supplied to the clock buffer 50 according to the clock signal CLK and the activation command ACT CMD. In addition, the jitter generated in the clock buffer 50 may be reduced by preventing a sudden drop in the output voltage V_{OUT}.

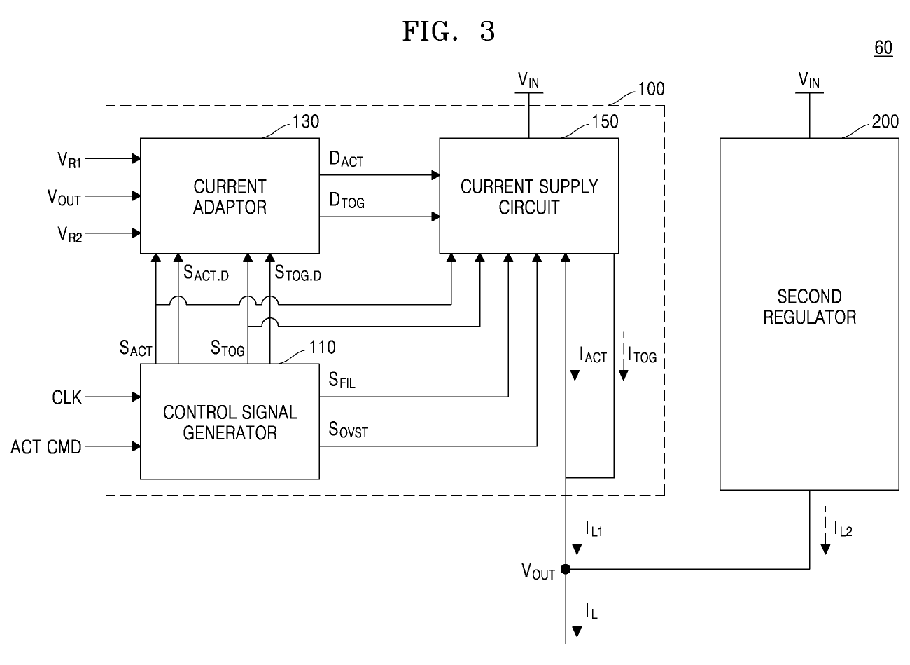

More specific structures and operations of the regulating device 60 are described with reference to FIG. 3 and below.

FIG. 3 is a diagram showing the regulating device 60 according to an embodiment.

Referring to FIG. 3, the regulating device 60 according to an embodiment may include a first regulator 100 and a second regulator 200.

In an embodiment, the first regulator 100 may supply first load current I_{L1} on the basis of the clock signal CLK and the activation command ACT CMD received from the host device 20.

In an embodiment, the first regulator 100 may include a control signal generator 110, a current adapter 130, and a current supply circuit 150.

In an embodiment, the control signal generator 110 may receive the clock signal CLK and the activation command ACT CMD. The control signal generator 110 may generate a plurality of control signals on the basis of the clock signal CLK and the activation command ACT CMD. The plurality of control signals may include signals for controlling operations or operation timings of components in the current adapter 130 or the current supply circuit 150. The plurality of control signals may include an activation control signal S_{ACT}, a delayed activation control signal S_{ACT}._{D}, a toggle control signal S_{TOG}, a delayed toggle control signal S_{TOG}._{D}, a filter control signal S_{FIL}, and an overshoot control signal S_{OVST}.

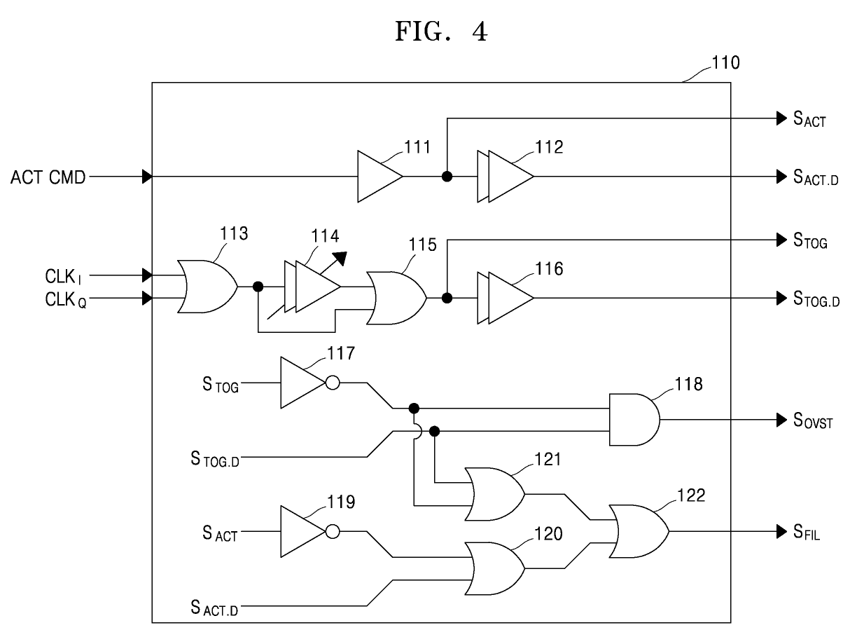

The control signal generator 110 may generate the activation control signal S_{ACT} on the basis of the activation command ACT CMD. The control signal generator 110 may generate the toggle control signal S_{TOG} on the basis of the clock signal CLK. The control signal generator 110 may delay the activation control signal S_{ACT} to generate the delayed activation control signal S_{ACT.D}. The control signal generator 110 may delay the toggle control signal S_{TOG} to generate the delayed toggle control signal S_{TOG.D}. The control signal generator 110 may generate the filter control signal S_{FIL} on the basis of the activation control signal S_{ACT} and the toggle control signal S_{TOG}. The control signal generator 110 may generate the overshoot control signal S_{OVST} on the basis of the toggle control signal S_{TOG}. More specific structures and operations of the control signal generator 110 are described below with reference to FIG. 4.

In an embodiment, the current adapter 130 may receive at least some of a plurality of control signals. The current adapter 130 may receive the activation control signal S_{ACT}, the delayed activation control signal S_{ACT.D}, the toggle control signal S_{TOG}, and the delayed toggle control signal S_{TOG.D}. In addition, the current adapter 130 may receive first reference voltage V_{R1}, second reference voltage V_{R2}, and the output voltage V_{OUT}.

The current adapter 130 may generate a plurality of adjustment values on the basis of at least some of the plurality of control signals. The plurality of adjustment values may represent the degree of adjustment of the output voltage V_{OUT}. The plurality of adjustment values may include an activation adjustment value D_{ACT} and a toggle adjustment value D_{TOG}.

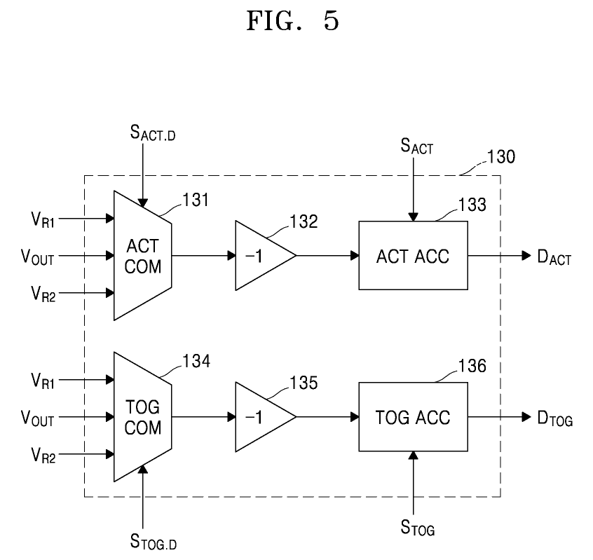

The current adapter 130 may generate the activation adjustment value D_{ACT} on the basis of the activation control signal S_{ACT}. The current adapter 130 may generate the toggle adjustment value D_{TOG} on the basis of the toggle control signal S_{TOG}. More specific structures and operations of the current adapter 130 are described below with reference to FIG. 5.

In an embodiment, the current supply circuit 150 may receive the plurality of adjustment values and at least some of the plurality of control signals. The current supply circuit 150 may receive the activation control signal S_{ACT}, the toggle control signal S_{TOG}, the activation adjustment value D_{ACT}, and the toggle adjustment value D_{TOG}. In addition, the current supply circuit 150 may receive the filter control signal S_{FIL} and the overshoot control signal S_{OVST}.

The current supply circuit 150 may supply the first load current I_{L1} on the basis of the plurality of adjustment values and at least some of the plurality of control signals. The current supply circuit 150 may supply activation load current I_{ACT} on the basis of the activation control signal S_{ACT}. The current supply circuit 150 may supply toggle load current I_{TOG} on the basis of the toggle control signal S_{TOG}. The activation load current I_{ACT} and the toggle load current I_{TOG} may be added together to form the first load current I_{L1}.

The current supply circuit 150 may prevent a sudden drop in the voltage applied to a switching element in the current supply circuit 150 on the basis of the filter control signal S_{FIL}. The current supply circuit 150 may prevent overshoot of the output voltage V_{OUT} on the basis of the overshoot control signal S_{OVST}.

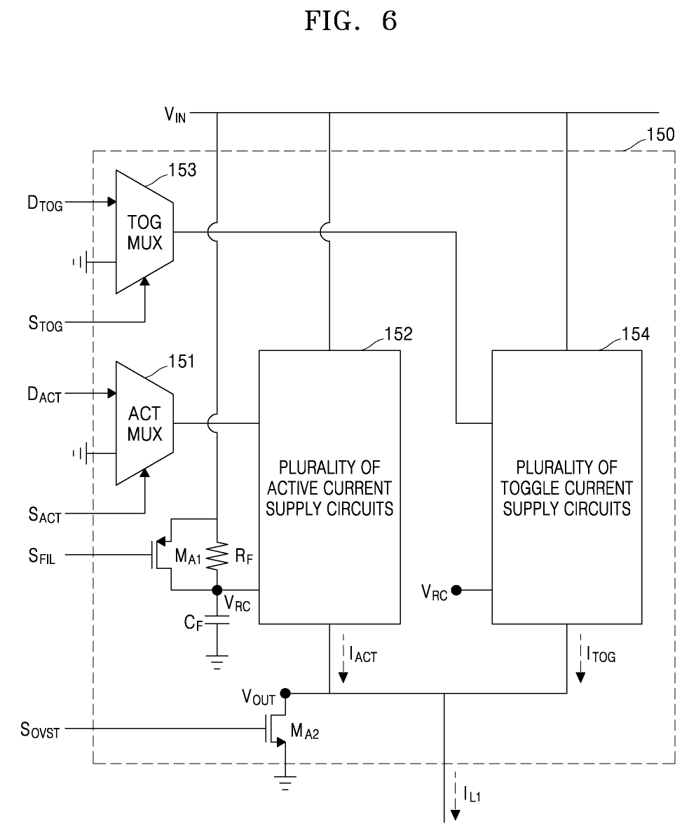

More specific structures and operations of the current supply circuit 150 are described below with reference to FIGS. 6 to 8.

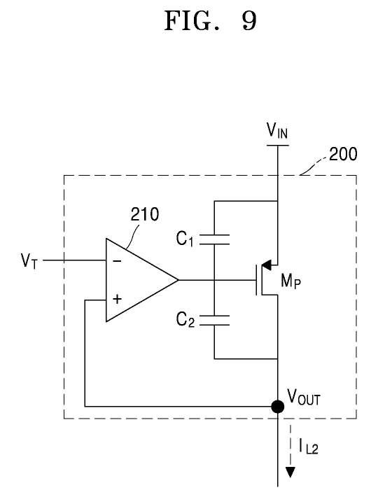

In an embodiment, the second regulator 200 may supply second load current I_{L2} on the basis of the output voltage V_{OUT} of the regulating device 60. The second regulator 200 may supply the second load current I_{L2} to compensate for the drop in the output voltage V_{OUT} that occurs despite the first load current I_{L1} supplied by the first regulator 100. More specific structures and operations of the second regulator 200 are described below with reference to FIG. 9.

FIG. 4 is a diagram showing the control signal generator 110 in a regulating device according to an embodiment.

FIG. 4 shows an example of the control signal generator 110.

The control signal generator 110 may include a first buffer 111.

The first buffer 111 may receive the activation command ACT CMD. The first buffer 111 may delay the activation command ACT CMD to generate the activation control signal S_{ACT}. The first buffer 111 may output the activation control signal S_{ACT}.

The control signal generator 110 may include a second buffer 112.

The second buffer 112 may receive the activation control signal S_{ACT}. The second buffer 112 may delay the activation control signal S_{ACT} to generate the delayed activation control signal S_{ACT.D}. The second buffer 112 may output the delayed activation control signal S_{ACT.D}.

The control signal generator 110 may include a first OR gate 113, a third buffer 114, and a second OR gate 115.

The first OR gate 113 may receive an I-phase signal CLK_{I} of the clock signal CLK and a Q-phase signal CLK_{Q} of the clock signal CLK, which is generated by delaying the I-phase signal CLK_{I} of the clock signal CLK by 90 degrees. The first OR gate 113 may output the result of performing a logical OR operation between the I-phase signal CLK_{I} of the clock signal CLK and the Q-phase signal CLK_{Q} of the clock signal CLK.

The third buffer 114 may receive the output signal of the first OR gate 113. The third buffer 114 may delay the output signal of the first OR gate 113 and then output the delayed output signal.

The second OR gate 115 may receive the output signal of the first OR gate 113 and the output signal of the third buffer 114. The second OR gate 115 may generate the toggle control signal S_{TOG} by performing a logical OR operation between the output signal of the first OR gate 113 and the output signal of the third buffer 114. The second OR gate 115 may output the toggle control signal S_{TOG}.

The control signal generator 110 may include a fourth buffer 116.

The fourth buffer 116 may receive the toggle control signal S_{TOG}. The fourth buffer 116 may delay the toggle control signal S_{TOG} to generate the delayed toggle control signal S_{TOG.D}. The fourth buffer 116 may output the delayed toggle control signal S_{TOG.D}.

The control signal generator 110 may include a first inverter 117 and an AND gate 118.

The first inverter 117 may receive the toggle control signal S_{TOG}. The first inverter 117 may invert the toggle control signal S_{TOG} and then output the inverted toggle control signal S_{TOG}.

The AND gate 118 may receive the output signal of the first inverter 117 and the delayed toggle control signal S_{TOG.D}. The AND gate 118 may generate the overshoot control signal S_{OVST} by performing a logical AND operation between the output signal of the first inverter 117 and the delayed toggle control signal S_{TOG.D}. The AND gate 118 may output the overshoot control signal S_{OVST}.

The control signal generator 110 may include a second inverter 119, a third OR gate 120, a fourth OR gate 121, and a fifth OR gate 122.

The second inverter 119 may receive the activation control signal S_{ACT}. The second inverter 119 may invert the activation control signal S_{ACT} and then output the inverted activation control signal S_{ACT}.

The third OR gate 120 may receive the delayed activation control signal S_{ACT.D} and the output signal of the second inverter 119. The third OR gate 120 may output the result of performing a logical OR operation between the delayed activation control signal S_{ACT.D} and the output signal of the second inverter 119.

The fourth OR gate 121 may receive the delayed toggle control signal S_{TOG.D} and the output signal of the first inverter 117. The fourth OR gate 121 may output the result of performing a logical OR operation between the delayed toggle control signal S_{TOG.D} and the output signal of the first inverter 117.

The fifth OR gate 122 may receive the output signal of the third OR gate 120 and the output signal of the fourth OR gate 121. The fifth OR gate 122 may generate the filter control signal S_{FIL} by performing a logical OR operation between the output signal of the third OR gate 120 and the output signal of the fourth OR gate 121. The fifth OR gate 122 may output the filter control signal S_{FIL}.

FIG. 5 is a diagram showing the current adapter 130 in a regulating device according to an embodiment.

Referring to FIG. 5, the current adapter 130 may include an activation comparator 131, an activation switch 132, an activation accumulator 133, a toggle comparator 134, a toggle switch 135, and a toggle accumulator 136.

The activation comparator 131 may receive the delayed activation control signal S_{ACT.D}, the first reference voltage V_{R1}, the second reference voltage V_{R2}, and the output voltage V_{OUT}. The activation comparator 131 may compare the output voltage V_{OUT} to the first reference voltage V_{R1} and the second reference voltage V_{R2} in response to the delayed activation control signal S_{ACT.D}. For example, when the delayed activation control signal S_{ACT.D} has the first value (e.g., 1), the activation comparator 131 may compare the first reference voltage V_{R1} and the second reference voltage V_{R2} to the output voltage V_{OUT}. In this case, when target voltage is defined as voltage having a voltage value required for the output voltage V_{OUT}, the first reference voltage V_{R1} may be greater than the target voltage by reference voltage (e.g., 10 mV), and the second reference voltage V_{R2} may be less than the target voltage by the reference voltage.

The activation comparator 131 may generate an activation comparison value by comparing the first reference voltage V_{R1} and the second reference voltage V_{R2} to the output voltage V_{OUT}. When the output voltage V_{OUT} is greater than the first reference voltage V_{R1}, the activation comparator 131 may generate a third value (e.g., 1) as the activation comparison value. When the output voltage V_{OUT} is less than the first reference voltage V_{R1} and greater than the second reference voltage V_{R2}, the activation comparator 131 may generate a fourth value (e.g., 0) as the activation comparison value. When the output voltage V_{OUT} is less than the second reference voltage V_{R2}, the activation comparator 131 may generate a fifth value (e.g., -1) as the activation comparison value. The activation comparator 131 may output the activation comparison value to the activation switch 132.

The activation switch 132 may receive the activation comparison value. The activation switch 132 may generate a switched activation comparison value by switching the sign of the activation comparison value. When the activation comparison value has the third value (e.g., 1), the activation switch 132 may generate the fifth value (e.g., -1) as the switched activation comparison value. When the activation comparison value has the fourth value (e.g., 0), the activation switch 132 may generate the fourth value (e.g., 0) as the switched activation comparison value. When the activation comparison value has the fifth value (e.g., -1), the activation switch 132 may generate the third value (e.g., 1) as the switched activation comparison value.

The activation accumulator 133 may receive the activation control signal S_{ACT} and the switched activation comparison value. The activation accumulator 133 may generate the activation adjustment value D_{ACT} by accumulating the switched activation comparison values in response to the activation control signal S_{ACT}. For example, the activation accumulator 133 may generate the activation adjustment value D_{ACT} by accumulating the switched activation comparison values when the activation control signal S_{ACT} has the first value (e.g., 1).

The activation adjustment value D_{ACT} may represent a value that is generated by accumulating the switched activation comparison values. When the output voltage V_{OUT} is greater than the first reference voltage V_{R1}, the switched activation comparison value has the fifth value (e.g., -1), and thus, the activation adjustment value D_{ACT} may decrease. On the other hand, when the output voltage V_{OUT} is less than the second reference voltage V_{R2}, the switched activation comparison value has the third value (e.g., 1), and thus, the activation adjustment value D_{ACT} may increase. Finally, when the output voltage V_{OUT} is less than the first reference voltage V_{R1} and greater than the second reference voltage V_{R2}, the switched activation comparison value has the fourth value (e.g., 0), and thus, the activation adjustment value D_{ACT} may not change.

The activation adjustment value D_{ACT} may include the same number of bits as a plurality of active current supply circuits 152 included in the current supply circuit 150, which is described below.

The activation adjustment value D_{ACT} may include binary code. The activation adjustment value D_{ACT} may increase or decrease according to the switched activation comparison value. For example, when the switched activation comparison value has the third value (e.g., 1), the activation adjustment value D_{ACT} may increase. On the other hand, when the switched activation comparison value has the fifth value (e.g., -1), the activation adjustment value D_{ACT} may decrease. Finally, when the switched activation comparison value has the fourth value (e.g., 0), the activation adjustment value D_{ACT} may remain unchanged.

The toggle comparator 134 may receive the delayed toggle control signal S_{TOG.D}, the first reference voltage V_{R1}, the second reference voltage V_{R2}, and the output voltage V_{OUT}. The toggle comparator 134 may compare the output voltage V_{OUT} to the first reference voltage V_{R1} and the second reference voltage V_{R2} in response to the delayed toggle control signal S_{TOG.D}. For example, when the delayed toggle control signal S_{TOG.D} has the first value (e.g., 1), the toggle comparator 134 may compare the first reference voltage V_{R1} and the second reference voltage V_{R2} to the output voltage V_{OUT}.

The toggle comparator 134 may generate a toggle comparison value by comparing the first reference voltage V_{R1} and the second reference voltage V_{R2} to the output voltage V_{OUT}. When the output voltage V_{OUT} is greater than the first reference voltage V_{R1}, the toggle comparator 134 may generate the third value (e.g., 1) as the toggle comparison value. When the output voltage V_{OUT} is less than the first reference voltage V_{R1} and greater than the second reference voltage V_{R2}, the toggle comparator 134 may generate the fourth value (e.g., 0) as the toggle comparison value. When the output voltage V_{OUT} is less than the second reference voltage V_{R2}, the toggle comparator 134 may generate the fifth value (e.g., -1) as the toggle comparison value. The toggle comparator 134 may output the toggle comparison value to the toggle switch 135.

The toggle switch 135 may receive the toggle comparison value. The toggle switch 135 may generate a switched toggle comparison value by switching the sign of the toggle comparison value. When the toggle comparison value has the third value (e.g., 1), the toggle switch 135 may generate the fifth value (e.g., -1) as the switched toggle comparison value. When the toggle comparison value has the fourth value (e.g., 0), the toggle switch 135 may generate the fourth value (e.g., 0) as the switched toggle comparison value. When the toggle comparison value has the fifth value (e.g., -1), the toggle switch 135 may generate the third value (e.g., 1) as the switched toggle comparison value.

The toggle accumulator 136 may receive the toggle control signal S_{TOG} and the switched toggle comparison value. The toggle accumulator 136 may generate the toggle adjustment value D_{TOG} by accumulating the switched toggle comparison values in response to the toggle control signal S_{TOG}. For example, the toggle accumulator 136 may generate the toggle adjustment value D_{TOG} by accumulating the switched toggle comparison values when the toggle control signal S_{TOG} has the first value (e.g., 1).

The toggle adjustment value D_{TOG} may represent a value that is generated by accumulating the switched toggle comparison values. When the output voltage V_{OUT} is greater than the first reference voltage V_{R1}, the switched toggle comparison value has the fifth value (e.g., -1), and thus, the toggle adjustment value D_{TOG} may decrease. On the other hand, when the output voltage V_{OUT} is less than the second reference voltage V_{R2}, the switched toggle comparison value has the third value (e.g., 1), and thus, the toggle adjustment value D_{TOG} may increase. Finally, when the output voltage V_{OUT} is less than the first reference voltage V_{R1} and greater than the second reference voltage V_{R2}, the switched toggle comparison value has the fourth value (e.g., 0), and thus, the toggle adjustment value D_{TOG} may not change.

The toggle adjustment value D_{TOG} may include the same number of bits as a plurality of toggle current supply circuits 154 included in the current supply circuit 150, which is described below.

The toggle adjustment value D_{TOG} may include binary code. The toggle adjustment value D_{TOG} may increase or decrease according to the switched toggle comparison value. For example, when the switched toggle comparison value has the third value (e.g., 1), the toggle adjustment value D_{TOG} may increase. On the other hand, when the switched toggle comparison value has the fifth value (e.g., -1), the toggle adjustment value D_{TOG} may decrease. Finally, when the switched toggle comparison value has the fourth value (e.g., 0), the toggle adjustment value D_{TOG} may remain unchanged.

FIG. 6 is a diagram showing the current supply circuit 150 in a regulating device according to an embodiment.

Referring to FIG. 6, the current supply circuit 150 may include an activation multiplexer 151, a plurality of active current supply circuits 152, a toggle multiplexer 153, and the plurality of toggle current supply circuits 154. The current supply circuit 150 may further include a first additional switching element M_{A1}, a filter resistor R_{F}, a filter capacitor C_{F}, and a second additional switching element M_{A2}.

The activation multiplexer 151 may receive the activation control signal S_{ACT}, the activation adjustment value D_{ACT}, and the ground voltage value (e.g., 0). The activation multiplexer 151 may selectively output one of the activation adjustment value D_{ACT} and the ground voltage value in response to the activation control signal S_{ACT}. For example, when the activation control signal S_{ACT} has the first value (e.g., 1), the activation multiplexer 151 may select and output the activation adjustment value D_{ACT}. On the other hand, when the activation control signal S_{ACT} has the second value (e.g., 0), the activation multiplexer 151 may select and output the ground voltage value.

The plurality of active current supply circuits 152 may output the activation load current I_{ACT} on the basis of the output value of the activation multiplexer 151.

The number of active current supply circuits 152 may be equal to the number of bits included in the activation adjustment value D_{ACT}. For example, the number of active current supply circuits 152 may be m, and the number of bits in the activation adjustment value D_{ACT} may also be m.

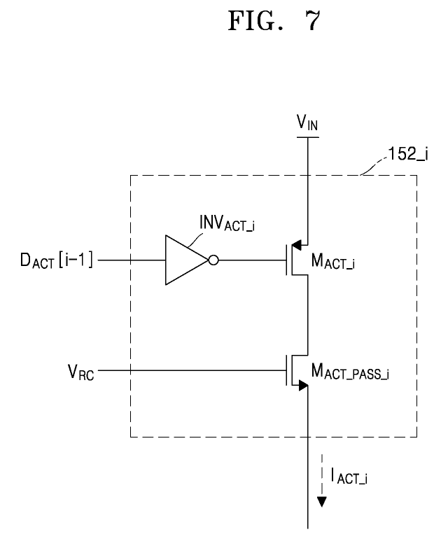

Each of the plurality of active current supply circuits 152 may output the activation load current I_{ACT} on the basis of one of the bits included in the output value of the activation multiplexer 151. More specific structures and operations of the plurality of active current supply circuits 152 are described below with reference to FIG. 7.

FIG. 7 is a diagram showing the active current supply circuit 152 in a regulating device according to an embodiment.

As an example, FIG. 7 shows a circuit diagram of an ith active current supply circuit 152_i that is one of the plurality of active current supply circuits 152. Each of the plurality of active current supply circuits 152 may include an activation inverter, an activation switching element, and an activation pass switching element. Hereinafter, the ith active current supply circuit 152_i (where i is an integer of 1 to m) is mainly described, but the following description may also equally apply to each of the plurality of active current supply circuits 152.

The ith active current supply circuit 152_i may include an ith activation inverter INV_{ACT_i}, an ith activation switching element M_{ACT_i}, and an ith activation pass switching element M_{ACT_PASS_i}.

The ith activation inverter INV_{ACT_i} may receive any one of the values of bits included in the output value of the activation multiplexer 151. For example, the ith activation inverter INV_{ACT_i} may receive the value of the bit located at the 2ⁱ⁻¹ place among the bits included in the output value of the activation multiplexer 151. For example, when the activation adjustment value D_{ACT} is selected by the activation multiplexer 151, the ith activation inverter INV_{ACT_i} may receive the value of a bit D_{ACT}[i-1] which is located at the 2ⁱ⁻¹ place of the activation adjustment value D_{ACT}. On the other hand, when the ground voltage value is selected by the activation multiplexer 151, the ith activation inverter INV_{ACT_i} may receive the ground voltage value.

The ith activation inverter INV_{ACT_i} may invert the received value and then output the inverted value. For example, when the activation adjustment value D_{ACT} is selected by the activation multiplexer 151, the ith activation inverter INV_{ACT_i} may invert the value of the bit D_{ACT}[i-1], which is located at the 2ⁱ⁻¹ place of the activation adjustment value D_{ACT}, and may then output the inverted value. On the other hand, when the ground voltage value is selected by the activation multiplexer 151, the ith activation inverter INV_{ACT_i} may invert the ground voltage value and then output the inverted value.

The ith activation switching element M_{ACT_i} may receive the output value of the ith activation inverter INV_{ACT_i}. In an embodiment, the ith activation switching element M_{ACT_i} may include a p-type metal oxide semiconductor (PMOS). However, the inventive concept is not limited thereto, and as a non-limiting example, the following description focuses on the embodiment in which the ith activation switching element M_{ACT_i} includes the PMOS.

A gate terminal of the ith activation switching element M_{ACT_i} may be connected to an output terminal of the ith activation inverter INV_{ACT_i}. The ith activation switching element M_{ACT_i} may receive an output value from the ith activation inverter INV_{ACT_i} via the gate terminal of the ith activation switching element M_{ACT_i}. A source terminal of the ith activation switching element M_{ACT_i} may be connected to a terminal of the input voltage V_{IN}. A drain terminal of the ith activation switching element M_{ACT_i} may be connected to a terminal of the output voltage V_{OUT} via the ith activation pass switching element M_{ACT_PASS_i}.

The ith activation switching element M_{ACT_i} may be turned on or off on the basis of the output value of the ith activation inverter INV_{ACT_i}. For example, when the output value of the ith activation inverter INV_{ACT_i} has the first value (e.g., 1), the ith activation switching element M_{ACT_i} may be turned off. On the other hand, when the output value of the ith activation inverter INV_{ACT_i} has the second value (e.g., 0), the ith activation switching element M_{ACT_i} may be turned on.

Depending on whether the ith activation switching element M_{ACT_i} is turned on or off, a connection between the terminal of the input voltage V_{IN} and the terminal of the output voltage V_{OUT} may be adjusted. For example, when turned on, the ith activation switching element M_{ACT_i} may connect the terminal of the input voltage V_{IN} to the terminal of the output voltage V_{OUT}. On the other hand, when turned off, the ith activation switching element M_{ACT_i} may not connect the terminal of the input voltage V_{IN} to the terminal of the output voltage V_{OUT}.

The ith activation switching element M_{ACT_i} may have a width proportional to 2ⁱ⁻¹. Accordingly, when the ith activation switching element M_{ACT_i} is turned on based on the ith activation inverter INV_{ACT_i}, current having a level proportional to 2ⁱ⁻¹ may be supplied to the ith activation pass switching element M_{ACT_PASS_i}. The ith activation pass switching element M_{ACT_PASS_i} may transmit the current, supplied from the ith activation switching element M_{ACT_i}, to the terminal of the output voltage V_{OUT}. For example, the ith activation pass switching element M_{ACT_PASS_i} may transmit, to the terminal of the output voltage V_{OUT}, the current that has a level proportional to 2ⁱ⁻¹ and supplied from the ith activation switching element M_{ACT_i}. In an embodiment, the ith activation pass switching element M_{ACT_PASS_i} may include an n-type metal oxide semiconductor (NMOS). However, the inventive concept is not limited thereto, and as a non-limiting example, the following description focuses on the embodiment in which the ith activation pass switching element M_{ACT_PASS_i} includes the NMOS.

A gate terminal of the ith activation pass switching element M_{ACT_PASS_i} may be connected to an RC voltage terminal V_{RC} (see FIG. 6). A drain terminal of the ith activation pass switching element M_{ACT_PASS_i} may be connected to the drain terminal of the ith activation switching element M_{ACT_i}. A source terminal of the ith activation pass switching element M_{ACT_PASS_i} may be connected to the terminal of the output voltage V_{OUT}.

The ith activation pass switching element M_{ACT_PASS_i} may be always turned on by RC voltage V_{RC} received via the gate terminal of the ith activation pass switching element M_{ACT_PASS_i}. That is, the ith activation pass switching element M_{ACT_PASS_i} may always connect the drain terminal of the ith activation switching element M_{ACT_i} to the terminal of the output voltage V_{OUT}. Therefore, depending on whether the ith activation switching element M_{ACT_i} is turned on or off, it may be determined whether ith activation load current I_{ACT_i} is supplied from the terminal of the input voltage V_{IN} to the terminal of the output voltage V_{OUT} via the ith active current supply circuit 152_i.

In this case, when the output value of the ith activation inverter INV_{ACT_i} has the second value (e.g., 0), the ith activation switching element M_{ACT_i} may be turned on. Therefore, when the activation adjustment value D_{ACT} is selected by the activation multiplexer 151, and the value of the bit D_{ACT}[i-1] located at the 2ⁱ⁻¹ place of the activation adjustment value D_{ACT} has the first value (e.g., 1), the ith activation switching element M_{ACT_i} is turned on. Accordingly, the ith activation load current I_{ACT_i} may be supplied from the terminal of the input voltage V_{IN} to the terminal of the output voltage V_{OUT} via the ith active current supply circuit 152_i.

Referring back to FIG. 6, currents output from the plurality of active current supply circuits 152 may be merged and then output as the activation load current I_{ACT}.

In this case, when the ground voltage value is selected by the activation multiplexer 151, the plurality of activation switching elements in the plurality of active current supply circuits 152 may all be turned off. That is, when the ground voltage value is selected by the activation multiplexer 151, the activation load current I_{ACT} may be 0.

On the other hand, when the activation adjustment value D_{ACT} is selected by the activation multiplexer 151, the activation load current I_{ACT} may be output via a number of active current supply circuits, corresponding to the number of bits having the first value (e.g., 1) among the bits in the activation adjustment value D_{ACT}, among the plurality of active current supply circuits 152.

The toggle multiplexer 153 may receive the toggle control signal S_{TOG}, the toggle adjustment value D_{TOG}, and the ground voltage value (e.g., 0). The toggle multiplexer 153 may selectively output one of the toggle adjustment value D_{TOG} and the ground voltage value in response to the toggle control signal S_{TOG}. For example, when the toggle control signal S_{TOG} has the first value (e.g., 1), the toggle multiplexer 153 may select and output the toggle adjustment value D_{TOG}. On the other hand, when the toggle control signal S_{TOG} has the second value (e.g., 0), the toggle multiplexer 153 may select and output the ground voltage value.

The plurality of toggle current supply circuits 154 may output the toggle load current I_{TOG} on the basis of the output value of the toggle multiplexer 153.

The number of toggle current supply circuits 154 may be equal to the number of bits included in the toggle adjustment value D_{TOG}. For example, the number of toggle current supply circuits 154 may be n, and the number of bits in the toggle adjustment value D_{TOG} may also be n.

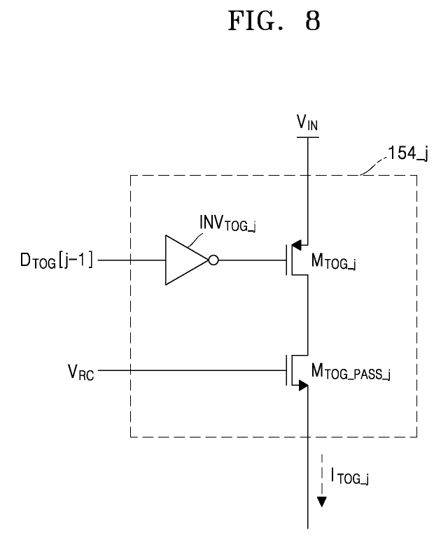

Each of the plurality of toggle current supply circuits 154 may output the toggle load current I_{TOG} on the basis of one of the bits included in the output value of the toggle multiplexer 153. More specific structures and operations of the plurality of toggle current supply circuits 154 are described below with reference to FIG. 8.

FIG. 8 is a diagram showing the toggle current supply circuit 154 in a regulating device according to an embodiment.

As a non-limiting example, FIG. 8 shows a circuit diagram of a jth toggle current supply circuit 154_j that is one of the plurality of toggle current supply circuits 154. Each of the plurality of toggle current supply circuits 154 may include a toggle inverter, a toggle switching element, and a toggle pass switching element. Hereinafter, the jth toggle current supply circuit 154_j (where j is an integer of 1 to n) is mainly described, but the following description may also apply to each of the plurality of toggle current supply circuits 154.

The jth toggle current supply circuit 154_j may include a jth toggle inverter INV_{TOG_j}, a jth toggle switching element M_{TOG_j}, and a jth toggle pass switching element M_{TOG_PASS_j}.

The jth toggle inverter INV_{TOG_j} may receive any one of the values of bits included in the output value of the toggle multiplexer 153. For example, the jth toggle inverter INV_{TOG_j} may receive the value of the bit located at the 2^{j-1} place among the bits included in the output value of the toggle multiplexer 153. For example, when the toggle adjustment value D_{TOG} is selected by the toggle multiplexer 153, the jth toggle inverter INV_{TOG_j} may receive the value of a bit D_{TOG}[j-1] located at the 2^{j-1} place of the toggle adjustment value D_{TOG}. On the other hand, when the ground voltage value is selected by the toggle multiplexer 153, the jth toggle inverter INV_{TOG_j} may receive the ground voltage value.

The jth toggle inverter INV_{TOG_j} may invert the received value and then output the inverted value. For example, when the toggle adjustment value D_{TOG} is selected by the toggle multiplexer 153, the jth toggle inverter INV_{TOG_j} may invert the value of the bit D_{TOG}[j-1], which is located at the 2^{j-1} place of the toggle adjustment value D_{TOG}, and may then output the inverted value. On the other hand, when the ground voltage value is selected by the toggle multiplexer 153, the jth toggle inverter INV_{TOG_j} may invert the ground voltage value and then output the inverted value.

The jth toggle switching element M_{TOG_j} may receive the output value of the jth toggle inverter INV_{TOG_j}. In an embodiment, the jth toggle switching element M_{TOG_j} may include a PMOS. However, the inventive concept is not limited thereto, and as a non-limiting example, the following description focuses on the embodiment in which the jth toggle switching element M_{TOG_j} includes the PMOS.

A gate terminal of the jth toggle switching element M_{TOG_j} may be connected to an output terminal of the jth toggle inverter INV_{TOG_j}. The jth toggle switching element M_{TOG_j} may receive the output value of the jth toggle inverter INV_{TOG_j} via the gate terminal of the jth toggle switching element M_{TOG_j}. A source terminal of the jth toggle switching element M_{TOG_j} may be connected to the terminal of the input voltage V_{IN}. A drain terminal of the jth toggle switching element M_{TOG_j} may be connected to the terminal of the output voltage V_{OUT} via the jth toggle pass switching element M_{TOG_PASS_j}.

The jth toggle switching element M_{TOG_j} may be turned on or off on the basis of the output value of the jth toggle inverter INV_{TOG_j}. For example, when the output value of the jth toggle inverter INV_{TOG_j} has the first value (e.g., 1), the jth toggle switching element M_{TOG_j} may be turned off. On the other hand, when the output value of the jth toggle inverter INV_{TOG_j} has the second value (e.g., 0), the jth toggle switching element M_{TOG_j} may be turned on.

Depending on whether the jth toggle switching element M_{TOG_j} is turned on or off, the connection between the terminal of the input voltage V_{IN} and the terminal of the output voltage V_{OUT} may be adjusted. For example, when turned on, the jth toggle switching element M_{TOG_j} may connect the terminal of the input voltage V_{IN} to the terminal of the output voltage V_{OUT}. On the other hand, when turned off, the jth toggle switching element M_{TOG_j} may not connect the terminal of the input voltage V_{IN} to the terminal of the output voltage V_{OUT}.

The jth toggle switching element M_{TOG_j} may have a width proportional to 2^{j-1}. Accordingly, when the jth toggle switching element M_{TOG_j} is turned on based on the jth toggle inverter INV_{TOG_j}, current having a level proportional to 2^{j-1} may be supplied to the jth toggle pass switching element M_{TOG_PASS_j}.

The jth toggle pass switching element M_{TOG_PASS_j} may transmit the current, supplied from the jth toggle switching element M_{TOG_j}, to the terminal of the output voltage V_{OUT}. For example, the jth toggle pass switching element M_{TOG_PASS_j} may transmit, to the terminal of the output voltage V_{OUT}, the current having a level proportional to 2^{j-1} and supplied from the jth toggle switching element M_{TOG_j}. In an embodiment, the jth toggle pass switching element _{MTOG_PASS_j} may include an NMOS. However, the inventive concept is not limited thereto, and as a non-limiting example, the following description focuses on the embodiment in which the jth toggle pass switching element M_{TOG_PASS_j} includes the NMOS.

A gate terminal of the jth toggle pass switching element M_{TOG_PASS_j} may be connected to the RC voltage terminal V_{RC} (see FIG. 6). A drain terminal of the jth toggle pass switching element M_{TOG_PASS_j} may be connected to the drain terminal of the jth toggle switching element M_{TOG_j}. A source terminal of the jth toggle pass switching element M_{TOG_PASS_j} may be connected to the terminal of the output voltage V_{OUT}.

The jth toggle pass switching element M_{TOG_PASS_j} may be always turned on by the RC voltage V_{RC} received via the gate terminal of the jth toggle pass switching element M_{TOG_PASS_j}. That is, the jth toggle pass switching element M_{TOG_PASS_j} may always connect the drain terminal of the jth toggle switching element M_{TOG_j} to the terminal of the output voltage V_{OUT}. Therefore, depending on whether the jth toggle switching element M_{TOG_j} is turned on or off, it may be determined whether jth toggle load current I_{TOG_j} is supplied from the terminal of the input voltage V_{IN} to the terminal of the output voltage V_{OUT} via the jth toggle current supply circuit 154_j.

In this case, when the output value of the jth toggle inverter INV_{TOG_j} has the second value (e.g., 0), the jth toggle switching element M_{TOG_j} may be turned on. Therefore, when the toggle adjustment value D_{TOG} is selected by the toggle multiplexer 153, and the value of the bit D_{TOG}[j-1] located at the 2^{j-1} place of the toggle adjustment value D_{TOG} has the first value (e.g., 1), the jth toggle switching element M_{TOG_j} is turned on. Accordingly, the jth toggle load current I_{TOG_j} may be supplied from the terminal of the input voltage V_{IN} to the terminal of the output voltage V_{OUT} via the jth toggle current supply circuit 154_j.

Referring back to FIG. 6, currents output from the plurality of toggle current supply circuits 154 may be merged and then output as the toggle load current I_{TOG}.

In this case, when the ground voltage value is selected by the toggle multiplexer 153, the plurality of toggle switching elements in the plurality of toggle current supply circuits 154 may all be turned off. That is, when the ground voltage value is selected by the toggle multiplexer 153, the toggle load current I_{TOG} may be 0.

On the other hand, when the toggle adjustment value D_{TOG} is selected by the toggle multiplexer 153, the toggle load current I_{TOG} may be output via a number of toggle current supply circuits, corresponding to the number of bits having the first value (e.g., 1) among the bits in the toggle adjustment value D_{TOG}, among the plurality of toggle current supply circuits 154.

In an embodiment, the number of active current supply circuits 152 may be less than the number of toggle current supply circuits 154. The plurality of active current supply circuits 152 may compensate for the change in the output voltage V_{OUT} caused by current consumption of the clock buffer 50 generated according to the value of the activation command ACT CMD. The plurality of toggle current supply circuits 154 may compensate for the change in the output voltage V_{OUT} caused by the current consumption of the clock buffer 50 generated according to the value of the clock signal CLK. In this case, since the change in the output voltage V_{OUT} due to the current consumption of the clock buffer 50 generated according to the value of the activation command ACT CMD is less than the change in the output voltage V_{OUT} due to the current consumption of the clock buffer 50 generated according to the value of the clock signal CLK, the number of active current supply circuits 152 may be less than the number of toggle current supply circuits 154.

The first additional switching element M_{A1} may receive the filter control signal S_{FIL}. In an embodiment, the first additional switching element M_{A1} may include a PMOS. However, the inventive concept is not limited thereto, and as a non-limiting example, the following description focuses on the embodiment in which the first additional switching element M_{A1} includes the PMOS.

A gate terminal of the first additional switching element M_{A1} may be connected to an output terminal of the control signal generator 110 for the filter control signal S_{FIL}. A drain terminal of the first additional switching element M_{A1} may be connected to the terminal of the input voltage V_{IN}. A source terminal of the first additional switching element M_{A1} may be connected to the RC voltage terminal V_{RC} and may also be connected to a ground voltage terminal via the filter capacitor C_{F}.

The first additional switching element M_{A1} may be turned on or off on the basis of the filter control signal S_{FIL}. The first additional switching element M_{A1} may be turned on based on the filter control signal S_{FIL} to connect the terminal of the input voltage V_{IN} to the RC voltage terminal V_{RC}, thereby preventing a sudden drop in the RC voltage V_{RC}.

The filter resistor R_{F} may be connected in parallel to the first additional switching element M_{A1}. More specifically, one end of the filter resistor R_{F} may be connected to the drain terminal of the first additional switching element M_{A1}, and the other end of the filter resistor R_{F} may be connected to the source terminal of the first additional switching element M_{A1}.

The filter capacitor C_{F} may be connected between the filter resistor R_{F} and the ground voltage terminal. More specifically, one end of the filter capacitor C_{F} may be connected to the other end of the filter resistor R_{F}, and the other end of the filter capacitor C_{F} may be connected to the ground voltage terminal.

The filter resistor R_{F} and the filter capacitor C_{F} may operate as a low-pass filter. The filter resistor R_{F} and the filter capacitor C_{F} operate as the low-pass filter and may thus improve power-supply rejection (PSR) performance in a high-frequency band of the first regulator 100.

The second additional switching element M_{A2} may receive the overshoot control signal S_{OVST}. In an embodiment, the second additional switching element M_{A2} may include an NMOS. However, the inventive concept is not limited thereto, and as a non-limiting example, the following description focuses on the embodiment in which the second additional switching element M_{A2} includes the NMOS.

A gate terminal of the second additional switching element M_{A2} may be connected to an output terminal of the control signal generator 110 for the overshoot control signal S_{OVST}. A drain terminal of the second additional switching element M_{A2} may be connected to the terminal of the output voltage V_{OUT}. A source terminal of the second additional switching element M_{A2} may be connected to the ground voltage terminal.

The second additional switching element M_{A2} may be turned on or off on the basis of the overshoot control signal S_{OVST}. The second additional switching element M_{A2} may be turned on based on the overshoot control signal S_{OVST} to connect the terminal of the output voltage V_{OUT} to the ground voltage terminal, thereby preventing overshoot of the output voltage V_{OUT}.

FIG. 9 is a diagram showing the second regulator 200 in a regulating device according to an embodiment.

Referring to FIG. 9, the second regulator 200 may include an amplifier 210, a switching element M_{P}, a first capacitor C₁, and a second capacitor C₂.

The amplifier 210 may receive target voltage V_{T} and the output voltage V_{OUT}. The amplifier 210 may amplify and output the difference between the target voltage V_{T} and the output voltage V_{OUT}. An output value of the amplifier 210 may be input to the switching element M_{P}.

The switching element M_{P} may receive the output value of the amplifier 210. In an embodiment, the switching element M_{P} may include a PMOS. However, the inventive concept is not limited thereto, and as a non-limiting example, the following description focuses on the embodiment in which the switching element M_{P} includes the PMOS.

A gate terminal of the switching element M_{P} may be connected to an output terminal of the amplifier 210. A drain terminal of the switching element M_{P} may be connected to the terminal of the output voltage V_{OUT}. A source terminal of the switching element M_{P} may be connected to the terminal of the input voltage V_{IN}.

Based on the output value of the amplifier 210, the degree to which the switching element M_{P} is turned on may be determined. In proportion to the degree to which the switching element M_{P} is turned on, the terminal of the input voltage V_{IN} may be connected to the terminal of the output voltage V_{OUT}, thereby adjusting the level of the second load current I_{L2}.

The first capacitor C₁ may be connected between the source terminal of the switching element M_{P} and the gate terminal of the switching element M_{P.} That is, one end of the first capacitor C₁ may be connected to the source terminal of the switching element M_{P}, and the other end of the first capacitor C₁ may be connected to the gate terminal of the switching element M_{P}.

The second capacitor C₂ may be connected between the drain terminal of the switching element M_{P} and the gate terminal of the switching element M_{P}. That is, one end of the second capacitor C₂ may be connected to the drain terminal of the switching element M_{P}, and the other end of the second capacitor C₂ may be connected to the gate terminal of the switching element M_{P}.

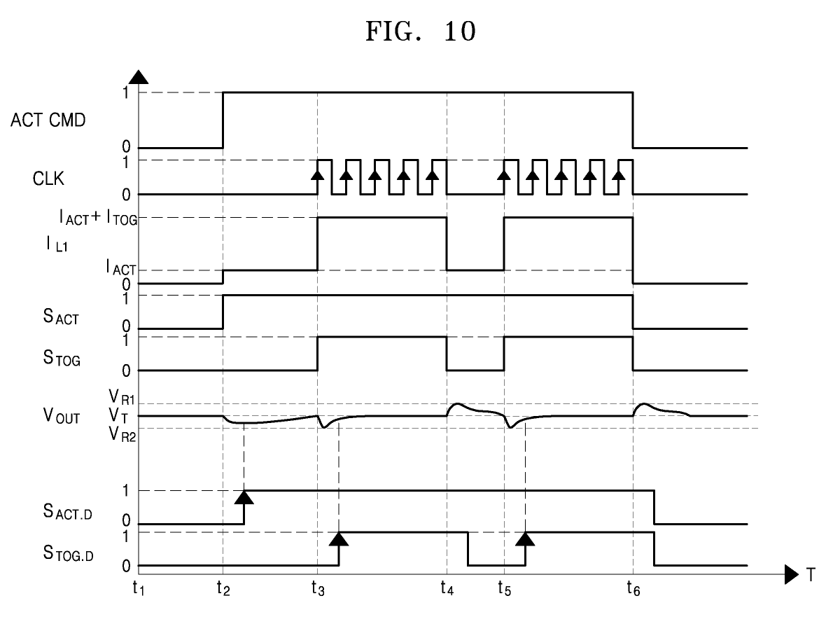

FIG. 10 is a timing diagram showing changes in signal values, current values, and voltage values according to operations of a regulating device according to an embodiment.

It can be seen that FIG. 10 is a graph showing changes over time T in the activation command ACT CMD, the clock signal CLK, the first load current I_{L1}, the activation control signal S_{ACT}, the toggle control signal S_{TOG}, the output voltage V_{OUT}, the delayed activation control signal S_{ACT.D}, and the delayed toggle control signal S_{TOG.D}.

First, in a section between a first time point t₁ and a second time point t₂, the values of the activation command ACT CMD are 0, which indicates that no clock signal CLK is applied. In this case, all values of the clock signal CLK may be 0, representing a state in which no clock signal CLK is applied. In this case, the values of the first load current I_{L1}, the activation control signal S_{ACT}, the toggle control signal S_{TOG}, the delayed activation control signal S_{ACT.D}, and the delayed toggle control signal S_{TOG.D} may all be 0. Also, the output voltage V_{OUT} may have the same value as the target voltage V_{T}.

Next, in a section between the second time point t₂ and a third time point t₃, the values of the activation command ACT CMD are 1, which indicates that the clock signal CLK may be applied. In this case, all values of the clock signal CLK may be 0, representing a state in which no clock signal CLK is applied.

As the value of the activation command ACT CMD becomes 1, the value of the activation control signal S_{ACT} may change to 1. In this case, the value of the activation control signal S_{ACT} may become 1, and after a short period of time, the value of the delayed activation control signal S_{ACT.D} may change to 1. Accordingly, the value of the first load current I_{L1} may become the value of the activation load current I_{ACT}.

Since the clock signal CLK is not applied, all values of the toggle control signal S_{TOG} and the delayed toggle control signal S_{TOG.D} may be 0.

In this case, as the first load current I_{L1} having the value of the activation load current I_{ACT} is applied, the output voltage V_{OUT} has a value less than the first reference voltage V_{R1} and greater than the second reference voltage V_{R2}. Therefore, the change in the output voltage V_{OUT} may be minimized.

Next, in a section between the third time point t₃ and a fourth time point t₄, the values of the activation command ACT CMD are 1, which indicates that the clock signal CLK may be applied. In this case, the value of the clock signal CLK may toggle between about 0 and about 1, representing a state in which the clock signal CLK is applied.

The value of the activation control signal S_{ACT} and the value of the delayed activation control signal S_{ACT.D} may remain at 1.

As the clock signal CLK is applied, the value of the toggle control signal S_{TOG} may change to 1. In this case, the value of the toggle control signal S_{TOG} may become 1, and after a short period of time, the value of the delayed toggle control signal S_{TOG.D} may change to 1. Accordingly, the value of the first load current I_{L1} may be the sum of the value of the activation load current I_{ACT} and the value of the toggle load current I_{TOG}.

In this case, as the first load current I_{L1} having a value equal to the sum of the value of the activation load current I_{ACT} and the value of the toggle load current I_{TOG} is applied, the output voltage V_{OUT} has a value less than the first reference voltage V_{R1} and greater than the second reference voltage V_{R2}. Therefore, the change in the output voltage V_{OUT} may be minimized.

Next, in a section between the fourth time point t₄ and a fifth time point t₅, the values of the activation command ACT CMD are 1, which indicates that the clock signal CLK may be applied. In this case, all values of the clock signal CLK may become 0, representing a state in which no clock signal CLK is applied.

The value of the activation control signal S_{ACT} and the value of the delayed activation control signal S_{ACT.D} may remain at 1.

As the clock signal CLK is not applied, the value of the toggle control signal S_{TOG} may change to 0. In this case, the value of the toggle control signal S_{TOG} may become 0, and after a short period of time, the value of the delayed toggle control signal S_{TOG.D} may change to 0. Accordingly, the value of the first load current I_{L1} may be reduced to the value of the activation load current I_{ACT}.

Next, in a section between the fifth time point t₅ and a sixth time point t₆, the values of the activation command ACT CMD are 1, which indicates that the clock signal CLK may be applied. In this case, the value of the clock signal CLK may toggle between about 0 and about 1, representing a state in which the clock signal CLK is applied.

The changes in the activation control signal S_{ACT}, the delayed activation control signal S_{ACT.D}, the toggle control signal S_{TOG}, the delayed toggle control signal S_{TOG.D}, the first load current I_{L1}, and the output voltage V_{OUT} in the section between the fifth time point t₅ and the sixth time point t₆ may be the same as the changes in those in the section between the third time point t₃ and the fourth time point t₄.

In a section after the sixth time point t₆, the values of the activation command ACT CMD are 0, which indicates that no clock signal CLK is applied. In this case, all values of the clock signal CLK may be 0, representing a state in which no clock signal CLK is applied. That is, input of the activation command ACT CMD and the clock signal CLK may stop.

In this case, as the value of the activation command ACT CMD and the value of the clock signal CLK become 0, the values of the activation control signal S_{ACT} and the toggle control signal S_{TOG} may also become 0, and after a short period of time, the values of the delayed activation control signal S_{ACT.D} and the delayed toggle control signal S_{TOG.D} may become 0.

Accordingly, the value of the first load current I_{L1} may change to 0. In this case, the output voltage V_{OUT} may have a value less than the first reference voltage V_{R1} and greater than the second reference voltage V_{R2} and may then become equal to the target voltage V_{T}.

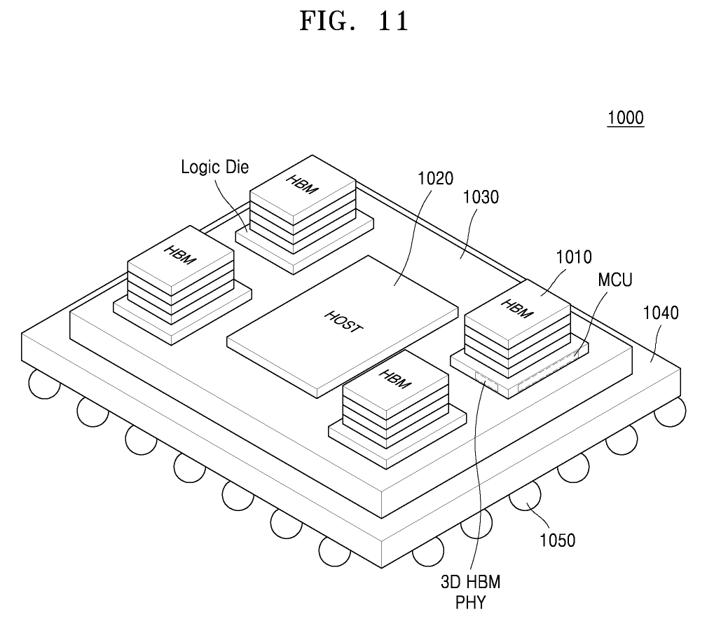

FIG. 11 is a diagram showing an example of a computing system including a clock buffering device according to embodiments.

Referring to FIG. 11, an electronic system 1000 may include one or more HBMs 1010 and a host 1020 according to embodiments. The HBMs 1010 and the host 1020 may be mounted on an interposer 1030, and the interposer 1030 equipped with the HBMs 1010 and the host 1020 may be mounted on a package substrate 1040. The host 1020 may correspond to various semiconductor devices that request memory access.

Each of the HBMs 1010 may include the memory device 30 described above with reference to FIG. 1. More specifically, the HBM 1010 may be implemented as the regulating device 60 that includes the first regulator 100 and the second regulator 200 described above with reference to FIGS. 2 to 10. In this case, the regulating device 60 may adjust the amount of load current on the basis of the clock signal CLK and the activation command ACT CMD received from the host 1020, thereby preventing a sudden drop in the power supply voltage supplied to the clock buffer 50 inside the HBM 1010.

The HBM 1010 may include a logic die and a plurality of core dies stacked thereon, and the logic die may include a memory control unit MCU. Also, when the HBM 1010 includes a direct access (DA) region, a test signal may be provided into the HBM 1010 via the DA region and a conductive means (e.g., a solder ball 1050) mounted on the bottom of the package substrate 1040. The interposer 1030 may be provided as various other structures, such as a through silicon via (TSV) type, an organic type in a printed circuit board (PCB) form, and an embedded multi-die interconnect bridge (EMIB) in a non-TSV form.

While the inventive concept has been particularly shown and described with reference to embodiments thereof, it will be understood that various changes in form and details may be made therein without departing from the spirit and scope of the following claims.

What is claimed is:

1. A regulating device comprising:
a first regulator configured to supply first load current, based on a clock signal and an activation command received from a host device; and
a second regulator configured to supply second load current based on output voltage of the regulating device,
wherein the first regulator comprises:
a control signal generator configured to generate a plurality of control signals, based on the clock signal and the activation command;
a current adapter configured to generate a plurality of adjustment values representing a degree of adjustment of the output voltage, based on at least some of the plurality of control signals; and
a current supply circuit configured to supply the first load current, based on at least some of the plurality of control signals and the plurality of adjustment values.

2. The regulating device of claim 1, wherein the control signal generator is configured to:
generate an activation control signal among the plurality of control signals based on the activation command; and
generate a toggle control signal among the plurality of control signals based on the clock signal.

3. The regulating device of claim 2, wherein the control signal generator is configured to:
generate a filter control signal among the plurality of control signals, based on the activation control signal and the toggle control signal; and
generate an overshoot control signal among the plurality of control signals based on the toggle control signal.

4. The regulating device of claim 1, wherein the current adapter is configured to:
generate an activation adjustment value among the plurality of adjustment values based on an activation control signal among the plurality of control signals; and
generate a toggle adjustment value among the plurality of adjustment values based on a toggle control signal among the plurality of control signals.

5. The regulating device of claim 4, wherein the current adapter comprises:
an activation comparator configured to generate an activation comparison value by comparing the output voltage to first reference voltage and second reference voltage, in response to a delayed activation control signal generated by delaying the activation control signal;
an activation switch configured to generate a switched activation comparison value by switching a sign of the activation comparison value;
an activation accumulator configured to generate the activation adjustment value by accumulating the switched activation comparison value, in response to the activation control signal;
a toggle comparator configured to generate a toggle comparison value by comparing the output voltage to the first reference voltage and the second reference voltage, in response to a delayed toggle control signal generated by delaying the toggle control signal;
a toggle switch configured to generate a switched toggle comparison value by switching a sign of the toggle comparison value; and
a toggle accumulator configured to generate the toggle adjustment value by accumulating the switched toggle comparison value, in response to the toggle control signal.

6. The regulating device of claim 1, wherein the current supply circuit comprises:
an activation multiplexer configured to selectively output one of 0 and an activation adjustment value among the plurality of adjustment values based on an activation control signal among the plurality of control signals;
a plurality of active current supply circuits configured to output activation load current based on an output value of the activation multiplexer;
a toggle multiplexer configured to selectively output one of 0 and a toggle adjustment value among the plurality of adjustment values based on a toggle control signal among the plurality of control signals; and
a plurality of toggle current supply circuits configured to output toggle load current based on an output value of the toggle multiplexer.

7. The regulating device of claim 6, wherein each of the plurality of active current supply circuits comprises:
an activation inverter configured to invert a value of one of bits in the output value of the activation multiplexer and output the inverted value;
an activation switching element configured to be turned on or off based on an output value of the activation inverter and adjust connection between an input voltage terminal and an output voltage terminal; and
an activation pass switching element configured to transmit current supplied from the activation switching element to the output voltage terminal, and
wherein each of the plurality of toggle current supply circuits comprises:
a toggle inverter configured to invert a value of one of bits in the output value of the toggle multiplexer and output the inverted value;
a toggle switching element configured to be turned on or off based on an output value of the toggle inverter and adjust the connection between the input voltage terminal and the output voltage terminal; and
a toggle pass switching element configured to transmit current supplied from the toggle switching element to the output voltage terminal.

8. The regulating device of claim 7, wherein a number of active current supply circuits is less than a number of toggle current supply circuits.

9. The regulating device of claim 7, wherein the current supply circuit further comprises:
a first additional switching element connected between the input voltage terminal and a ground voltage terminal and configured to be turned on or off based on a filter control signal among the plurality of control signals;
a filter resistor connected in parallel to the first additional switching element; and
a filter capacitor connected between the filter resistor and the ground voltage terminal.

10. The regulating device of claim 6, further comprising a second additional switching element connected between an output voltage terminal and a ground voltage terminal and configured to be turned on or off based on an overshoot control signal among the plurality of control signals.

11. A clock buffering device configured to receive a clock signal and an activation command from a host device and output a buffered clock signal based on the clock signal, the clock buffering device comprising:
a clock buffer configured to buffer the clock signal and output the buffered clock signal; and
a regulating device configured to supply first load current and second load current to the clock buffer, based on the clock signal and the activation command,
wherein the regulating device comprises:
a first regulator configured to supply the first load current, based on the clock signal and the activation command; and
a second regulator configured to supply the second load current based on output voltage of the regulating device, and
wherein the first regulator comprises:
a control signal generator configured to generate an activation control signal and a toggle control signal, based on the clock signal and the activation command;
a current adapter configured to generate a plurality of adjustment values representing a degree of adjustment of the output voltage, based on the activation control signal and the toggle control signal; and
a current supply circuit configured to supply the first load current, based on the activation control signal, the toggle control signal, and the plurality of adjustment values.

12. The clock buffering device of claim 11, wherein the control signal generator is configured to:
generate the activation control signal based on the activation command; and
generate the toggle control signal based on the clock signal.

13. The clock buffering device of claim 11, wherein the current adapter is configured to:
generate an activation adjustment value among the plurality of adjustment values based on the activation control signal; and
generate a toggle adjustment value among the plurality of adjustment values based on the toggle control signal.

14. The clock buffering device of claim 13, wherein the current adapter comprises:
an activation comparator configured to generate an activation comparison value by comparing the output voltage to first reference voltage and second reference voltage, in response to a delayed activation control signal generated by delaying the activation control signal;
an activation switch configured to generate a switched activation comparison value by switching a sign of the activation comparison value;
an activation accumulator configured to generate the activation adjustment value by accumulating the switched activation comparison value, in response to the activation control signal;
a toggle comparator configured to generate a toggle comparison value by comparing the output voltage to the first reference voltage and the second reference voltage, in response to a delayed toggle control signal generated by delaying the toggle control signal;
a toggle switch configured to generate a switched toggle comparison value by switching a sign of the toggle comparison value; and
a toggle accumulator configured to generate the toggle adjustment value by accumulating the switched toggle comparison value, in response to the toggle control signal.

15. The clock buffering device of claim 11, wherein the current supply circuit comprises:
an activation multiplexer configured to selectively output one of 0 and an activation adjustment value among the plurality of adjustment values based on the activation control signal;
a plurality of active current supply circuits configured to output activation load current based on an output value of the activation multiplexer;
a toggle multiplexer configured to selectively output one of 0 and a toggle adjustment value among the plurality of adjustment values based on the toggle control signal; and
a plurality of toggle current supply circuits configured to output toggle load current based on an output value of the toggle multiplexer.

16. The clock buffering device of claim 15, wherein each of the plurality of active current supply circuits comprises:
an activation inverter configured to invert a value of one of bits in the output value of the activation multiplexer and output the inverted value;
an activation switching element configured to be turned on or off based on an output value of the activation inverter and adjust connection between an input voltage terminal and an output voltage terminal; and
an activation pass switching element configured to transmit current supplied from the activation switching element to the output voltage terminal, and
wherein each of the plurality of toggle current supply circuits comprises:
a toggle inverter configured to invert a value of one of bits in the output value of the toggle multiplexer and output the inverted value;
a toggle switching element configured to be turned on or off based on an output value of the toggle inverter and adjust the connection between the input voltage terminal and the output voltage terminal; and
a toggle pass switching element configured to transmit current supplied from the toggle switching element to the output voltage terminal.

17. The clock buffering device of claim 11, wherein the control signal generator is configured to:
generate a filter control signal, based on the activation control signal and the toggle control signal; and
generate an overshoot control signal based on the toggle control signal.

18. The clock buffering device of claim 17, wherein the current supply circuit further comprises a filter circuit comprising:
a first additional switching element connected between an input voltage terminal and a ground voltage terminal and configured to be turned on or off based on the filter control signal;
a filter resistor connected in parallel to the first additional switching element; and
a filter capacitor connected between the filter resistor and the ground voltage terminal.

19. The clock buffering device of claim 17, further comprising a second additional switching element connected between an output voltage terminal and a ground voltage terminal and configured to be turned on or off based on an overshoot control signal.

20. A computing system comprising:
a host device; and
a memory device configured to receive a clock signal and an activation command from the host device,
wherein the memory device comprises a clock buffering device configured to receive the clock signal and the activation command and output a buffered clock signal based on the clock signal, and
the clock buffering device comprises:
a clock buffer configured to buffer the clock signal and output the buffered clock signal; and
a regulating device configured to supply first load current and second load current to the clock buffer, based on the clock signal and the activation command, and
wherein the regulating device comprises:
a first regulator configured to supply the first load current, based on the clock signal and the activation command; and
a second regulator configured to supply the second load current based on output voltage of the regulating device, and
wherein the first regulator comprises:
a control signal generator configured to generate a plurality of control signals, based on the clock signal and the activation command;
a current adapter configured to generate a plurality of adjustment values representing a degree of adjustment of the output voltage, based on at least some of the plurality of control signals; and
a current supply circuit configured to supply the first load current, based on at least some of the plurality of control signals and the plurality of adjustment values.
